(19) United States
(12) Patent Application Publication
(10) Pub. No.: US 2009/0260571 A1
(43) Pub. Date: Oct. 22, 2009

(54) Showerhead for chemical vapor deposition

(75) Inventors: John Ostrowski, Lake Oswego, OR (US); Percy Verdeflor, Fremont, CA (US)

Correspondence Address: Weaver Austin Villeneuve & Sampson LLP - NOVL;Attn.: Novellus Systems, Inc., P.O. Box 70250, Oakland, CA, 94612-0250, US

(73) Assignee: Novellus Systems, Inc.

(21) Appl. No.: 12/148,267

(22) Filed: Apr. 16, 2008

(51) Int. Cl. C23C 16/00

(52) U.S. Cl. 118/728

(57) ABSTRACT

A CVD showerhead is connected to a chamber top via a leveling assembly. The leveling assembly allows the showerhead to pivot when a bellows in the leveling assembly is adjusted from outside the chamber. With the improved showerhead, leveling calibration can occur from outside of the chamber without having to pressurize and open the chamber top. Thus downtime is reduced.

### FIELD OF THE INVENTION

The present invention pertains to apparatus and systems for depositing films on a substrate. Specifically, the invention pertains to a chemical vapor deposition (CVD) apparatus. Even more specifically, the invention pertains to a showerhead and a leveling assembly.

### BACKGROUND

CVD showerhead reactors employ a perforated or porous planar surface to dispense reactant and carrier gases as uniformly as possible over a second parallel planar surface. This configuration can be used for continuous batch processing of multiple substrates or processing of single round wafers. Wafers are generally heated to a process temperature at which the reactant gases react and deposit a film on the wafer surface.

Showerhead reactors, or parallel-plate reactors, lend themselves to implementation of plasma-enhanced processes, e.g., plasma-enhanced chemical vapor deposition (PECVD). In most PECVD reactors the top and bottom electrodes are about the same size. The wafer electrode may be a substrate support and be grounded and the showerhead may have RF power applied. Bias RF power may be applied to the substrate support. The applied RF in the showerhead may necessitate insulating sections in the gas supply system to avoid creating a parasitic discharge in the gas feed lines to the chamber. RF power may be applied through the substrate support electrode, while the showerhead may be grounded.

Wafer-to-wafer uniformity may be affected by variations in reaction temperature from wafer-to-wafer: process conditions, clean cycles, idling time, and change in emissivity of the showerhead components over time can all affect the substrate or wafer as well as the gas reaction temperature. Within-wafer uniformity may be affected by non-uniform wafer heating and cooling, process gas distribution, plasma densities, and distance between the wafer surface and the showerhead. Non-uniform distance between the wafer surface and the showerhead at various locations on the wafer causes temperature and process gas flow variations across the wafer.

It is therefore desirable to accurately and quickly level the showerhead in a chamber to minimize within wafer non-uniformity.

### SUMMARY OF THE INVENTION

A CVD showerhead is connected to a chamber top plate via a leveling assembly. The leveling assembly includes a bellows that allows the showerhead to pivot when it is adjusted from outside the chamber. A showerhead stem includes a flange that engages a recessed feature in the bellows. With the improved showerhead, leveling calibration can occur from outside of the chamber without having to break vacuum and open the chamber top. Thus downtime is reduced.

In one aspect, the present invention pertains to a CVD showerhead apparatus that includes a showerhead and a leveling assembly. The showerhead includes a face, a back plate attached to the face, a stem attached to the back plate, and a stem flange on the stem. The leveling assembly includes a bellows that has a recessed feature to receive the stem flange. The bellows is attached to a chamber top plate and, when adjusted, permits pivoting of the showerhead apparatus relative to the chamber top plate. The pivoting levels the showerhead face with respect to a wafer support.

According to various embodiments, the leveling assembly also includes a ceramic collar that is connected to the bellows and the chamber top plate. The ceramic collar electrically insulates the showerhead apparatus from the chamber top plate, which is typically made of metal. The leveling assembly forms a vacuum seal against the chamber top plate and the stem. The leveling assembly may also include a showerhead flange that has a concave surface proximate to the bellows and a convex surface oriented distally from the showerhead. The showerhead flange may be placed in a housing that has a socket to receive the convex surface of the showerhead flange. A locking ring locks the showerhead in place.

In certain embodiments, the showerhead stem includes an inner cavity and an outer cavity. The outer cavity is annularly disposed around the inner cavity. The stem flange is located on the stem distal from the back plate. The stem flange passes through the bellows in one angular orientation and rigidly engages the recessed feature in the bellows in another angular orientation. The showerhead is not connected to the top plate by means other than the stem and leveling assembly. There are no top plate stand-offs.

In another aspect, the present invention pertains to a PECVD chamber. The chamber includes a wafer support, a top plate, and a showerhead. The showerhead has a face, a back plate, and a stem. The stem is attached to the top plate through a leveling assembly. The assembly includes a joint attached to the top plate and the stem. The joint is configured to permit pivoting the stem when it is adjusted so that the showerhead can be leveled. The leveling assembly also includes a locking ring that is configured to lock the joint in a position. The only engagement of the showerhead with the top plate is via the stem, which is electrically insulated from the top plate. A ceramic material may provide the insulation. The leveling assembly may form a vacuum seal against the chamber top plate and the stem.

According to various embodiments, the showerhead stem also includes a stem flange configured to rigidly attach to the joint. The attachment may be at a recessed, or keyed, feature in the joint. The stem flange may be located on the stem on the further end from the back plate. The showerhead stem may include an inner and an outer stem for flowing a heat transfer fluid in between and for flowing a gas in the inner stem. In other words, the showerhead may include an inner and an outer cavity. The inner cavity is for flowing process gas and the outer cavity, a heating transfer fluid.

In yet another aspect, the present invention pertains to a showerhead. The showerhead has a face, a back plate attached to the face, a stem attached to the back plate, and a stem flange on the stem located distally from the back plate. The stem flange is configured to pass through a recessed engagement feature in one angular orientation and to rigidly engage the recessed engagement feature in another angular orientation. The recessed feature and the stem flange may be configured as a lock and a key.

In one aspect, the present invention also pertains to a method of leveling a showerhead in the deposition chamber. A gapping tool is positioned on a wafer support. The tool may be positioned by a robot through cassette, or positioned manually through an open chamber top plate. The showerhead is leveled by pivoting a stem relative to the chamber top from the exterior of the chamber. The pivoting may be accomplished electromechanically or manually. The pivoting may occur through a gimbal mechanism, a bellows, or a joint. The showerhead is locked in position after a desired stem position, and hence showerhead face position, is reached. The method may also include measuring at two or more locations the distances between the gapping tool and a showerhead surface, positioning the showerhead by pivoting a stem relative to the chamber top such that differences between the plurality of distances are reduced, and repeating the measuring and moving operation until the differences between the plurality of distances are less than a specified tolerance. The gapping tool may be a test wafer apparatus configured to capacitively measure a distance or a solid block having a specific dimension. The solid block may be ceramic.

These and other features and advantages of the invention will be described in more detail below with reference to the associated drawings.

### BRIEF DESCRIPTION OF THE DRAWINGS

FIG. 1 is a schematic of a process chamber including a showerhead in accordance with various embodiments.

FIG. 2 is an exploded diagram of a showerhead, a chamber top, and a leveling assembly in accordance with various embodiments of the present invention.

FIG. 3A is a cross-section schematic diagram of an installed showerhead and leveling assembly in accordance with various embodiments of the present invention.

FIG. 3B is a 3-D view of the showerhead of FIG. 3.

FIG. 4 is a process flow diagram of a leveling method in accordance with various embodiments of the present invention.

FIG. 5 is a process flow diagram of a leveling method in accordance with various embodiments of the present invention.

### DETAILED DESCRIPTION OF SPECIFIC EMBODIMENTS

### Introduction

In the following detailed description of the present invention, numerous specific embodiments are set forth in order to provide a thorough understanding of the invention. However, as will be apparent to those skilled in the art, the present invention may be practiced without these specific details or by using alternate elements or processes. In other instances well-known processes, procedures and components have not been described in detail so as not to unnecessarily obscure aspects of the present invention.

In this application, the terms “substrate” and “wafer” will be used interchangeably. The following detailed description assumes the invention is implemented on semiconductor processing equipment. However, the invention is not so limited. The apparatus may be utilized to process work pieces of various shapes, sizes, and materials. In addition to semiconductor wafers, other work pieces that may take advantage of this invention include various articles such as display face planes, printed circuit boards, solar cell wafers, Micro-Electro-Mechanical Systems (MEMS), and the like.

Deposition reactions in a chemical vapor deposition (CVD) a chamber depend on a number of the chamber conditions. Typically, reaction rates depend at least on the rate of process gas flow, chamber temperature and pressure, wafer temperature, and plasma conditions if plasma is used. Variation of these conditions across a wafer may affect within wafer uniformity. Within wafer non-uniformity means that the film deposited at one location on the wafer, e.g., the edge, the center, has film property that is different from a film deposited at another location on the wafer. Within wafer non-uniformity (WIWNU) is typically expressed as a percentage of standard deviation from average value of the film property of interest. For CVD films, a typical film property may be thickness deposited or stress.

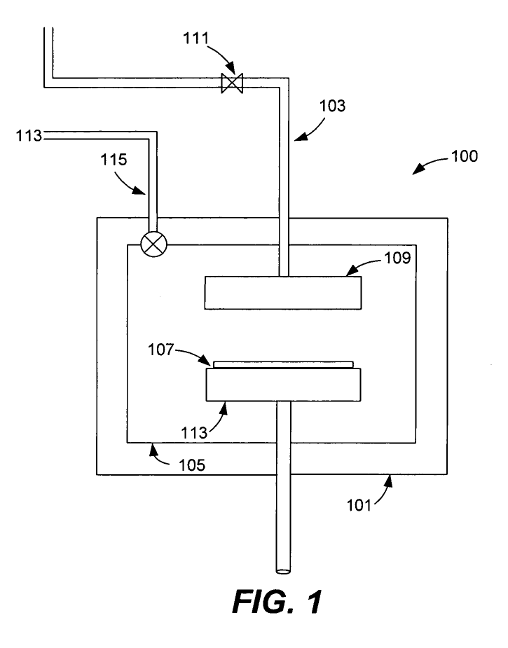

FIG. 1 is a schematic of a process chamber 100 that incorporates a showerhead. The enclosure 101 forms the outer boundary of the chamber. The internal space 105 is often pressure controlled, typically in a vacuum during deposition. A wafer 107 is positioned on a wafer support (pedestal) 113 during processing. The pedestal may be heated with a heat exchanging fluid or with electrical resistance and may transfer heat to the wafer which it supports. In some cases, a heat transfer gas enters the back side of the wafer from the pedestal to aid in such heat transfer. A showerhead 109 is positioned opposite from the pedestal on the other side of the wafer. Process gas enters the showerhead 109 through gas lines 103 and one or more flow control valves 111. At the showerhead, the process gas is dispersed and exits the showerhead typically through perforations on the showerhead face. A process gas may be heated before it enters the showerhead. One or more vacuum forelines 115 may control the chamber pressure by evacuating the chamber to one or more vacuum sources 113, e.g., a vacuum pump.

Variation in temperatures across the wafer surface may affect the reaction rate and cause within wafer non-uniformity. During processing, a wafer is in a dynamic environment, and its temperatures change with time. The wafer temperature may be at an ambient temperature when it enters a chamber. When it is positioned on a heated pedestal, its temperature rapidly increases, depending on the temperature difference and heat transfer qualities of the gas in the chamber. The showerhead also affects the temperature of the wafer surface. If the showerhead is cooler than the wafer, the showerhead may cool the wafer. The distance between the showerhead and the wafer determines the effect of such heat transfer. When the showerhead and the wafer are positioned close to each other, more heat transfer takes place. The distance between the showerhead and the wafer also affects how the process gas flow affects wafer temperature. If cool process gas reaches the wafer at a high velocity, it may cool the wafer. Chamber walls also contribute to the wafer temperature. Typically wafer edges are cooler than the center because of the edge's proximity to cooler surfaces such as chamber walls and carrier rings if used.

The distance between the wafer and the showerhead, also known as the showerhead gap, contributes to wafer temperature in at least two ways: by directly affecting heat transfer between the two; and, by affecting process gas velocity. When this distance varies across the wafer because the showerhead is tilted or not leveled, the wafer surface temperature and other chamber properties may be affected. Wafer temperature and other properties caused by this distance variation can cause within wafer non-uniformity in the film as deposited. Thus, it is desirable to position the showerhead face plate so that it is in parallel with the wafer support and therefore the wafer surface. Parallelism or level can be obtained when distances between the showerhead face plate surface and the wafer support at several locations are within a certain range. Usually, at least three showerhead gap measurements are taken at different radii and angles to verify a showerhead is level. In one embodiment, a showerhead is level when all showerhead gaps are set to within 0.001 inch.

The showerhead gap also affects the film property in other ways. In a multistation chamber, a wafer is transferred from one station to another and experiences processing in each station. When the showerhead gaps vary from station to station, the reaction and thus the film properties deposited also vary. A wafer may receive different processing at one station to the next if the gaps are different. Thus it is also preferable to maintain a same showerhead gap in each station of a multistation chamber.

In some designs, one or more o-rings are used in the assembly between the showerhead and a chamber top. These o-rings can retain induced stresses when a showerhead is leveled. These induced stresses cause a leveled showerhead to become tilted over time. Usually, a showerhead is leveled when the WIWNU becomes high, above a certain threshold, or after a certain amount of time or processing, e.g., a number of hours, total film deposited, or a number of wafers processed.

A showerhead leveling is typically performed with a wet clean procedure that involves cooling and venting the chamber one or multiple times. The cooling and venting may be required to access the interior of the chamber to adjust the spacing between the showerhead and the chamber top and thereby leveling the showerhead. A conventional technique involves placing metallic foil balls in the chamber to measure the showerhead gap and then adjusting a number of standoffs, usually three or more, between a back plate of the showerhead and the chamber top based on the measurements. The standoffs can only be adjusted by opening the chamber top after venting and cooling the chamber. Multiple measuring and adjusting cycles may be performed before the showerhead is considered level. Because the showerhead cannot be leveled through external manipulation, the process can be very time-consuming, up to about 20 hours.

The present invention addresses these issues. A showerhead and leveling assembly is designed to be leveled from outside of the chamber, even while the chamber is under vacuum (does not require venting). The showerhead and leveling assembly design also reduced or eliminates parts that retain induced stresses that can subsequently tilt a leveled showerhead. Thus, not only the leveling time is shorter, the duration between leveling may also be longer. In some cases, the chamber uptime is increased by reducing the duration and frequency of scheduled downtimes.

There are generally two main types of CVD showerheads: the chandelier type and the flush mount. The chandelier showerheads have a stem attached to the top of the chamber on one end and the face plate on the other end, resembling a chandelier. A part of the stem may protrude the chamber top to enable connection of gas lines and RF power. The flush mount showerheads are integrated into the top of a chamber and do not have a stem. The present invention pertains to a chandelier type showerhead.

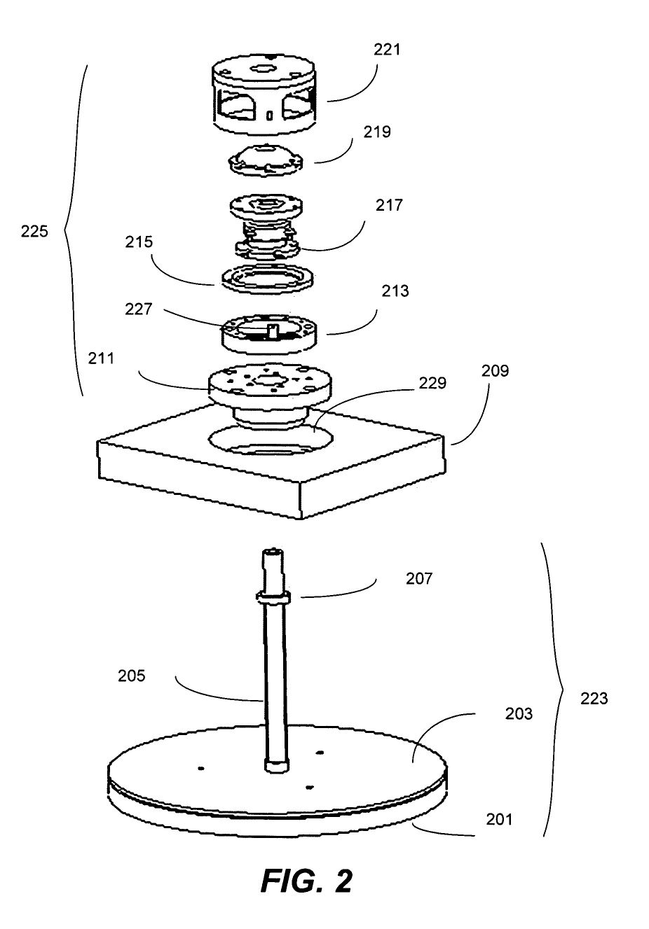

FIG. 2 is an exploded diagram of various components of the showerhead and leveling assembly in accordance with various embodiments of the present invention. The showerhead 223 includes a face plate 201, a back plate 203, a showerhead stem 205, and a stem flange 207. The face plate 201 is the part of the showerhead closest to a wafer during processing. The face plate 201 is perforated to allow process gas to pass to the wafer. Typically, the perforations are in a pattern to effect an even distribution of process gas across the wafer. The face plate 201 is attached to the back plate 203. In addition to the connection to the back plate at the circumferential edge, the face plate may also be attached to the back plate at various points internally. Attached to the back plate 203 on the other side of the face plate 201 is the showerhead stem 205. The showerhead stem allows gas to flow through from outside of the chamber to the face plate. The gas may be a combination of various process gases and inert/carrier gases. The stem may include one or more inner cavities: one for process gas flow and one for heat transfer fluid flow. Heat transfer fluid flow allows the showerhead temperature to be separately controlled from other components of the chamber. Showerhead temperature control may be desirable for certain processes. Of course, the showerhead stem would then be configured with appropriate inlet and outlet for the heat transfer fluid. At a portion of the showerhead stem 205 positioned distally from the back plate 203 is the stem flange 207. The stem flange is a part of the showerhead stem 205 and allows the showerhead to be engaged into a bellows in the leveling assembly. The shape of the stem flange is such that it can slide through an opening in the bellows in one angular orientation and be engaged in another angular orientation, like a lock and key. In one embodiment, the showerhead is about 8.4 inches long as measured from the bottom surface of the face plate to the top of the stem. The showerhead flange is located about 1.5 inches from the top of the stem and is thus about 6.9 inches from the face plate. The stem flange is in the shape of a cylinder with three notches approximately 120 degrees apart. The notches roughly span 60 degrees.

In a typical implementation, the showerhead stem slides up through an opening 229 in the chamber top plate 209, through a collar 211, a shoulder 213, a locking ring 215, a bellows 217, a showerhead flange 219, and a housing 221. Collectively, the collar 211, shoulder 213, locking ring 215, bellows 217, showerhead flange 219, and housing 221 are referred to as the leveling assembly 225. Through the top of housing 221, the showerhead stem 207 connects to input gas lines.

The chamber top plate 209 shown is a part of the chamber. The chamber top may include one or more openings 229 to accommodate one or more showerheads. A single station chamber has only one showerhead, and thus only one opening 229. A multiple station chamber may include multiple showerheads, one for each station, and thus multiple openings 229. The collar 211 is attached to the chamber top, which is typically made of a metallic material. The collar 211 physically separates the chamber top 209 from the showerhead stem 205 and is typically made of an insulating material, such as ceramic. Generally, RF energy is applied to the showerhead to generate plasma. The insulating collar ensures that the RF energy is not transmitted to the metallic chamber top. One of more bolts in the collar attaches the leveling assembly to the chamber top.

A shoulder 213 is attached to the top of the collar, as shown. The shoulder 213 also includes one or more brackets 227. The stem locking ring 215 is positioned on top of the shoulder 213. The bellows 217 is positioned on top of the collar through the shoulder plate. The bellows 217 is a device with flexible and lockable circumferential sidewalls and an inner annulus. The showerhead stem is attached to the bellows by seating the stem flange on the top of the bellows. The shape of the bellow top allows rigid attachment of the stem flange, which has a matching shape. The stem flange may pass through the bellows top in one angular orientation and becomes locked in another angular orientation. Once the stem flange is seated, the flexible sidewall of the bellows permits the stem to be pivoted so that the showerhead becomes level. According to one embodiment, the bellows is made of various metal rings that have been welded together that allow it to be flexible. The bellows may be locked in place by tightening a locking mechanism, e.g., the stem locking ring 215, against the showerhead. In other embodiments, a gimbal mechanism is used. The gimbal includes two or more rotatable rings. By rotating one or more rings but not others, a stem may be pivoted. Generally, a joint such as a universal joint or a ball joint that allows a showerhead stem to extend through and can be locked in position may be used.

A showerhead flange 219 is positioned on top of the bellows 217. In accordance with various embodiments of the present invention, the showerhead flange 219 has a concave surface proximate to the bellows and the stem flange and a convex surface away from the bellows. The showerhead flange 219 may be attached to the bellows over the stem flange with one or more fasteners to rigidly affix the stem flange relative to the bellows. A showerhead housing 221 covers the showerhead flange 210, the stem flange 207, the bellows 217, and the locking ring 215. The housing 221 may be attached to the bracket 227 of the shoulder 213. The housing 221 protects the leveling assembly components during normal operation of the chamber.

The leveling assembly 225 includes reduced number of o-rings and components that can retain induced stress as compared to previous designs. Together, the leveling assembly components provide a vacuum seal for the chamber while permitting the showerhead stem to feed through.

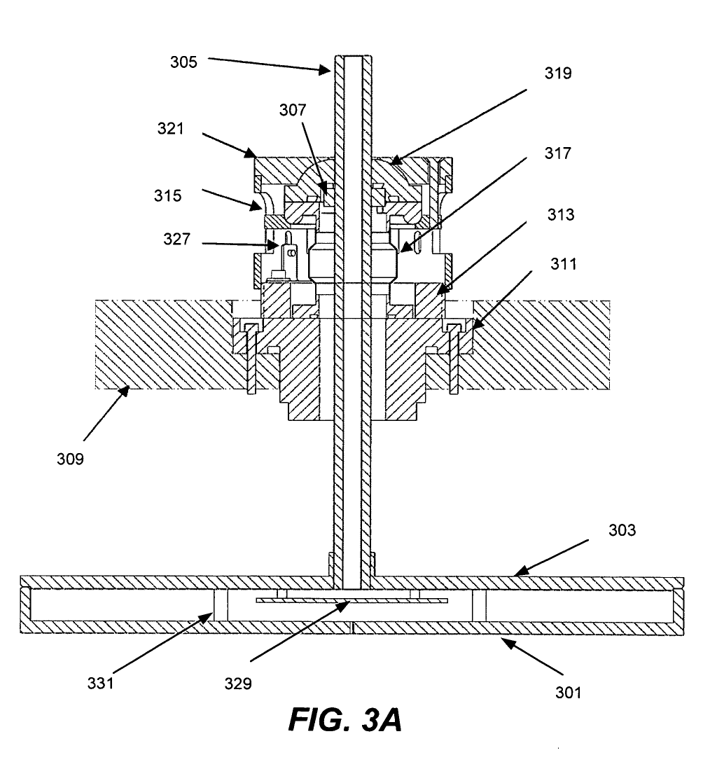

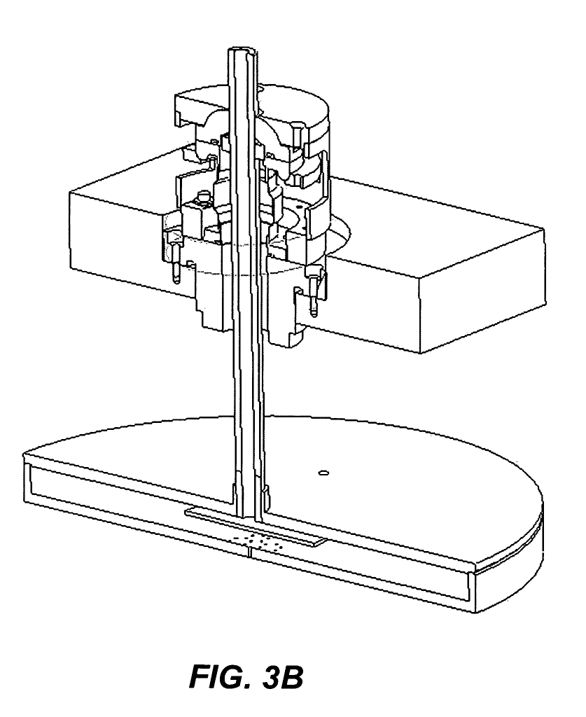

FIG. 3A is a cross-section diagram of an assembled showerhead and leveling assembly. Like features between FIGS. 2 and 3 are labeled alike. FIG. 3 shows a baffle positioned between the face plate 301 and back plate 303 of the showerhead. The baffle 329 serves to distribute injected gas evenly across the wafer. FIG. 3 also shows standoffs 331 between the face plate and the back plate for certain embodiments. Collar 311 is fastened into chamber top 309 at various points. As shown, the collar isolates the rest of the level assembly and the showerhead from the chamber top plate 309. As shown, the showerhead flange 319 encases the stem flange 307. FIG. 3B is a three-dimensional diagram of FIG. 3A.

In one aspect, the invention pertains to the entire chamber, for example, plasma enhanced CVD (PECVD) chamber. As discussed, a PECVD chamber may have one station or more than one station for processing a wafer. Typically, each station is configured with a pedestal and a showerhead. In some embodiments, a wafer is transferred from outside of the chamber to a first station, where it undergoes processing. Then the wafer is transferred to the next station for further processing. The wafer transferring and processing continues until the last station is reached, from which the wafer is transfer out of the chamber either to the next chamber or out of the system. In other embodiments, a wafer is not transferred from station to station. A wafer is transferred from outside of the chamber to a first station, where it undergoes processing. Then the wafer is simply transferred out of the chamber to the next station or out of the system.

A PECVD chamber in accordance with various embodiments of the present invention includes one or more stations, each station including a wafer support, a top plate, and a showerhead. The showerhead is connected to the top plate via a leveling assembly as described above. The assembly includes a joint, e.g., a bellows or a ball joint, attached to the top plate and the stem. The joint is configured to permit pivoting the stem when it is adjusted so that the showerhead can be leveled. The leveling assembly also includes a showerhead flange that allows for pivoting. A locking ring locks the joint in position after a showerhead is adjusted. The only engagement of the showerhead with the top plate is via the stem, which is electrically insulated from the top plate via a collar. The collar may be made of a ceramic material or other insulating material. The leveling assembly may form a vacuum seal against the chamber top plate and the stem.

In another aspect, the present invention pertains to a showerhead that has a face, a back plate attached to the face, a stem attached to the back plate, and a stem flange on the stem located distally from the back plate. The stem flange is a part of the stem and is configured to rigidly attach to a recessed engagement feature. The stem flange is configured to pass through a recessed engagement feature in one angular orientation and to rigidly engage the recessed engagement feature in another angular orientation. The recessed feature and the stem flange may be configured as a lock and a key.

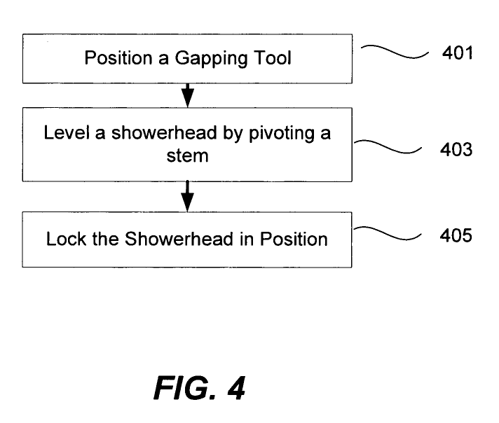

In accordance with various embodiments, a technique of leveling the showerhead is provided. FIG. 4 is a process flow diagram depicted various operations of the technique. A gapping tool is positioned on the wafer support in operation 401. A gapping tool may be of a block or cylinder type having a specific thickness that is equal to the desired showerhead gap. The gapping tool may be manufactured such that its top and bottom surfaces are parallel to each other to a very high degree. A first plane that is flush with one of the top or bottom surface of the gapping tool is then substantially parallel to a second plane that is flush with the other of the top or bottom surface of the gapping tool. The thickness variation across the gapping tool is no more than 0.001 inches, preferably less than 0.0005 inches. The gapping tool is made of a material, e.g., ceramic, that is compatible with a semiconductor processing chamber and does not deform when subjected to pressure and temperature cycling. Other types of gapping tools may be used, such as a remote capacitive gap sensor or other distance sensing tools.

The positioning operation may be performed by manually placing a gapping tool on a pedestal while a chamber top is open so that the chamber is accessible from outside of the tool. The position operation may also be performed remotely by a robot arm placing a gapping tool onto a pedestal. The gapping tool may be transferred via the robot from another chamber or a cassette such as a front opening unified pod.

When the gapping tool is in position, then the showerhead is leveled in operation 403. Generally, the showerhead is leveled by pivoting a stem. In certain embodiments, the pivoting involves adjusting one or more components of the leveling assembly to cause the stem to pivot. For example, the showerhead flange may be rotated to level the showerhead.

If a block or cylinder gapping tool is used, the showerhead stem is adjusted so that the showerhead face plate is completely flush with the gapping tool. In one embodiment, the showerhead is leveled by threading the showerhead housing down onto the collar threads. The threading action compresses the bellows and cause the showerhead stem to lower onto the gapping tool. The adjustment may involve one or more iterations of adjustment and verification operations. In some cases, the person doing the adjusting may visually verify that the showerhead face plate is flush with the gapping tool. In some cases, the verification may occur in other ways, such as mechanically or through a measurement. The adjustment may be performed electromechanically through a computer program controlling one or more devices configured to adjust the degree of pivot of the showerhead stem. When the showerhead level is verified, then the showerhead is locked in position at operation 405.

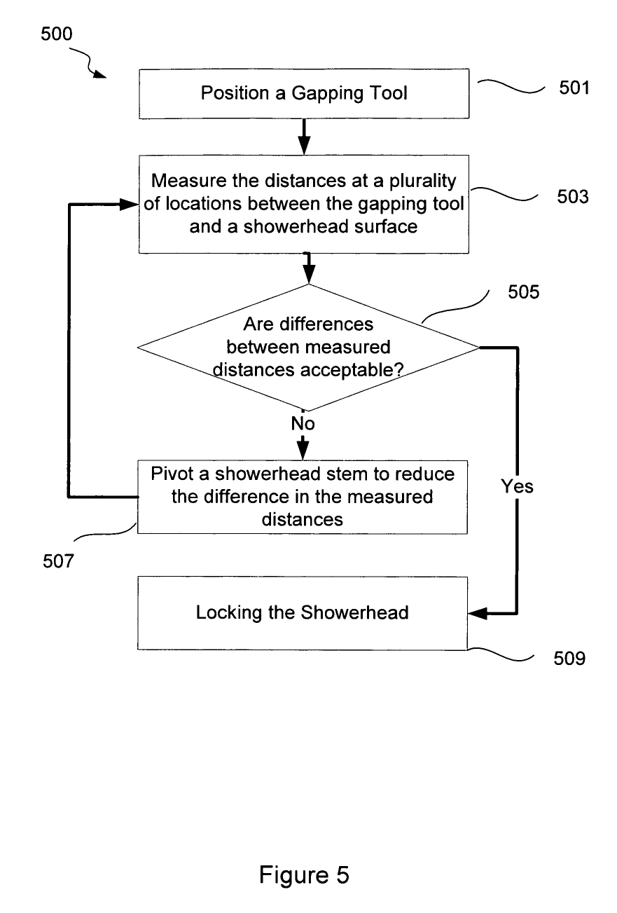

In certain embodiments, a technique as depicted in FIG. 5 may be used to level a showerhead. A gapping tool is positioned on the pedestal as described above in operation 501. The gapping tool may be a distance sensing tool such as capacitive sensors mounted on a wafer-shaped circuit board. A plurality of distances is measured between the gapping tool and a showerhead surface in operation 503. The plurality of distances is preferably at least three. The measurement locations are preferably at different angular positioned relative to the center of the pedestal and at difference radii or distances from the center. For example, measurement points may be at 0 degrees at the edge of the wafer-shaped circuit board, 120 degrees at a midpoint between the edge and center of the wafer-shaped circuit board, and at 240 degrees and close to the center of the wafer-shaped circuit board. In other examples, measurement points may simply be spaced out angularly but equally distant from the center of the wafer-shaped circuit board. In any case, the measurement points should be configured so that a determination can be made whether the showerhead face plate is parallel with respect to the wafer support. A capacitive gapping tool appropriate for the use with the present invention is the WaferSense Auto Gapping System by CyberOptics Semiconductor of Beaverton, Oreg.

Once the measurements are made, a computer program or a person may determine whether the differences between the measured distances are acceptable in operation 505. The acceptable criteria may be a range, a standard deviation, or an average, or a combination of these. If the differences are acceptable, then the showerhead is locked in operation 509 as described above. If the differences are not acceptable, the showerhead stem is pivoted to reduce the difference in the measured distances in operation 507. The pivoting operation is described above. The measurement and comparison operations are repeated in operation 503 and 505. The pivoting operation is repeated again if the new measurement is not acceptable.

The showerhead leveling technique described above allows a showerhead to be leveled with only one venting of the chamber and reducing downtime for showerhead leveling by as much as 60%, down to about 8 hours using a block gapping tool and about 4 hours using a gapping tool such as an automated gap sensor.

Although various details have been omitted for clarity's sake, various design alternatives may be implemented. Therefore, the present examples are to be considered as illustrative and not restrictive, and the invention is not to be limited to the details given herein, but may be modified within the scope of the appended claims.

What is claimed is:

1. A showerhead apparatus comprising:
(a) a showerhead comprising a face, a back plate attached to the face, a stem attached to the back plate, and a stem flange on the stem; and,
(b) a leveling assembly comprising a bellows having a recessed feature to receive the stem flange;
wherein the bellows is attached to a chamber top plate and is configured to permit pivoting of the showerhead apparatus.

2. The apparatus of claim 1, wherein the leveling assembly further comprises a ceramic collar coupled to the bellows and the chamber top plate while electrically insulating the showerhead apparatus from the chamber top plate.

3. The apparatus of claim 1, wherein the leveling assembly further comprises a showerhead flange coupled to the bellows and configured to lock the bellows in a desired position.

4. The apparatus of claim 3, wherein the showerhead flange comprises a first concave surface coupled to the bellows and a second convex surface oriented distally from the showerhead.

5. The apparatus of claim 4, wherein the leveling assembly further comprises a housing having a socket configured to receive the convex surface of the showerhead flange.

6. The apparatus of claim 1, wherein the stem comprises an inner cavity and an outer cavity annularly disposed around the inner cavity.

7. The apparatus of claim 1, wherein the leveling assembly forms vacuum seal against the chamber top plate and the stem.

8. The apparatus of claim 1, wherein the showerhead does not include engagement points for top plate standoffs.

9. The apparatus of claim 1, wherein the stem flange is in a position on the stem distal from the back plate.

10. The apparatus of claim 1, wherein the recessed feature is configured to allow the stem flange to pass through in one angular orientation and to rigidly engage the recessed feature in another angular orientation.

11. A PECVD chamber comprising:
(a) a wafer support;
(b) a top plate;
(c) a showerhead having a face, a back plate, and a stem, said stem attached to the top plate through a leveling assembly, said leveling assembly comprising:
i) a joint attached to the top plate and the stem, said joint configured to permit pivoting of the stem; and
ii) a showerhead flange configured to lock the joint in a position.
wherein the only engagement of the showerhead with the top plate is via the stem and the stem is electrically insulated from the top plate.

12. The chamber of claim 11, wherein a connection between the top plate and the stem comprises a ceramic material to provide electrical insulation.

13. The chamber of claim 11, wherein the stem further comprises a stem flange configured to rigidly attach to a recessed feature in the joint.

14. The chamber of claim 11, wherein the leveling assembly forms a vacuum seal against the chamber top plate and the stem.

15. The chamber of claim 11, wherein the stem comprises a stem flange located at a position on the stem distal from the back plate.

16. A showerhead comprising:
(a) a face;
(b) a back plate attached to the face;
(c) a stem attached to the back plate;
(d) a stem flange on the stem located distally from the back plate, said stem flange configured to pass through a recessed engagement feature in one angular orientation and to rigidly engage the recessed engagement feature in another angular orientation.

17. The showerhead of claim 16, wherein the stem comprises an inner and an outer stem for flowing a heat transfer fluid in between and for flowing a gas in the inner stem.

18. A method of leveling a showerhead in a deposition chamber, said method comprising:
(a) positioning a gapping tool on a wafer support;
(b) leveling the showerhead by pivoting a stem relative to the chamber top from the exterior of the chamber; and,
(c) locking the showerhead in position.

19. The method of claim 18, wherein the leveling operation comprises:
(a) measuring the distances at a plurality of locations between the gapping tool and a showerhead surface;
(b) positioning the showerhead by pivoting a stem relative to the chamber top such that differences between the plurality of distances are reduced; and,
(c) repeating the measuring and moving operation until the differences between the plurality of distances are less than a specified tolerance.
